(19) United States
(12) Patent Application Publication
(10) Pub. No.: US 2019/0373731 A1
(43) Pub. Date: Dec. 5, 2019

(54) DUMMY ELECTRONIC COMPONENT

(71) Applicant: Hewlett-Packard Development Company, L.P., Spring, TX (US)

(72) Inventors: Tiffany L Greyson, Boise, ID (US); Kristen N Gratalo, Boise, ID (US); Timothy J Gray, Boise, ID (US)

(21) Appl. No.: 16/462,718

(22) PCT Filed: Jan. 26, 2017
(86) PCT No.: PCT/US2017/015055

§ 371 Date: May 21, 2019

(51) Int. Cl. H05K 1/18; H05K 1/11; H05K 3/30

(52) U.S. Cl. CPC H05K 1/181; H05K 1/115; H05K 2201/2036; H05K 2201/10022; H05K 2201/10204; H05K 3/303

(57) ABSTRACT

An example device includes a planar circuit board with a first surface and a second surface opposite the first surface, an electrical circuit on at least one of the first surface or the second surface, and at least one dummy electronic component mounted on the first surface. The electrical circuit includes at least one electronic component. The dummy electronic component is electrically isolated from the electrical circuit. The dummy electronic component has a protrusion from the planar circuit board that is greater than protrusion of each of the at least one electronic component of the electrical circuit.

### BACKGROUND

Printed circuit boards are commonplace in a variety of electronic devices. A typical PCB includes one or more circuit formed on a substrate. The circuit may include numerous electrical components that are electrically coupled through, for example, electrical traces formed on the substrate.

### BRIEF DESCRIPTION OF THE DRAWINGS

For a more complete understanding of various examples, reference is now made to the following description taken in connection with the accompanying drawings in which:

FIG. 1 is an illustration of an example device with an electrical circuit on a circuit board;

FIG. 2 is an illustration of an example device with an electrical circuit on a circuit board;

FIG. 3 is a side view of the example device of FIG. 2;

FIG. 4 is a top view of the example device of FIG. 2;

FIG. 5 is a bottom view of the example device of FIG. 2;

FIG. 6 is a perspective view of an example system with an example device having an electrical circuit on a circuit board;

FIG. 7 is a side view of the example system of FIG. 6; and

FIG. 8 is a flow chart illustrating an example process.

### DETAILED DESCRIPTION

Various examples provide for using a dummy electronic component to provide standoff distance between a circuit board and a surface to which the circuit board is mounted. In some examples, a circuit board may be mounted to a mounting surface which may be the frame of a system, such as a printer or other imaging system, where the frame may be formed of a metal and, therefore, electrically conductive. Examples of the present disclosure provide using a low-cost dummy electrical component, such as a resistor, to achieve the standoff. The dummy electrical component is positioned on a mounting side of the circuit board, the mounting side being the side facing the mounting surface and is electrically isolated from a circuit or other electrical components on the circuit board. The dummy electrical component is physically large enough (e.g., larger than all other components on the mounting side of the circuit board) to provide electrical isolation between the circuit board and the mounting surface.

As described above, printed circuit boards (PCBs) typically includes one or more circuit formed on a substrate and may include numerous electrical components and electrical traces formed on the substrate. Such PCBs may be mounted to a surface for installation in a system, such as a printer or other imaging device, for example. In some cases, a PCB may be mounted on a mounting surface that may be an internal frame or structure of the system. When the mounting surface is formed of a metal or other conductive material, mounting of the PCB should be performed to ensure a standoff between the mounting surface and the circuit formed on the PCB.

In some cases, the desired standoff may be provided by placing spacers between the PCB and the mounting surface. However, such spacers can add significant cost, and placing of the spacers may require additional processes. Accordingly, the present disclosure describes example devices to facilitate mounting of the PCB on a mounting surface in an efficient and cost-effective manner.

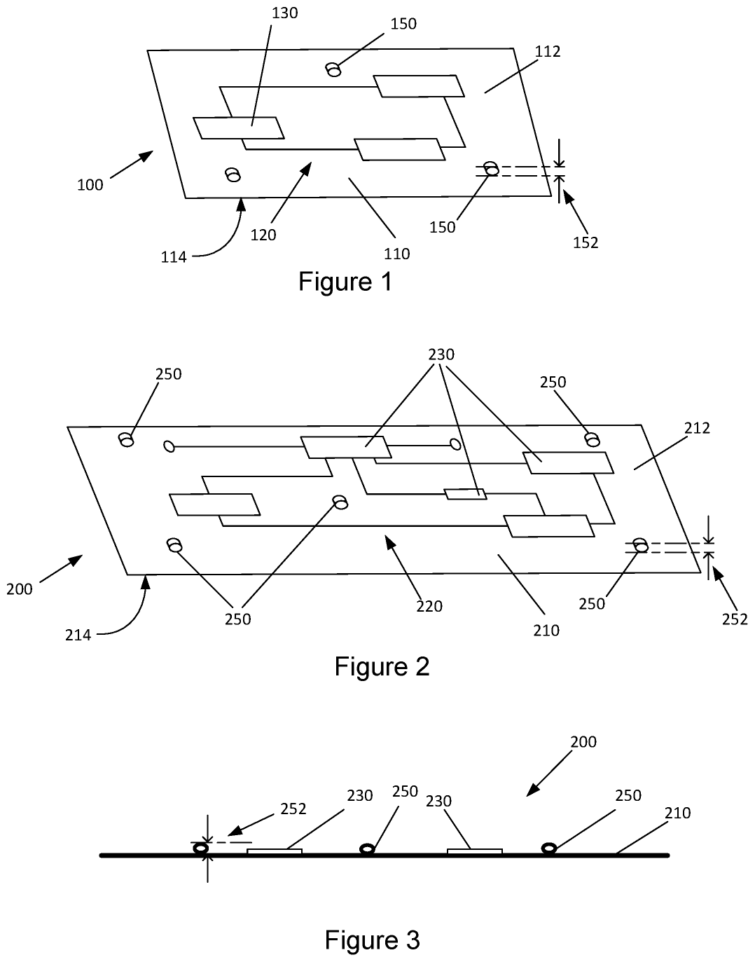

Referring now to the figures, FIG. 1 illustrates an example device with an electrical circuit on a circuit board. The example device 100 includes a planar circuit board 110 with a first surface 112 and a second surface 114 opposite the first surface 112. The example device 100 further includes an electrical circuit 120 on at least one of the first surface 112 or the second surface 114. In the example illustrated in FIG. 1, the electrical circuit 120 is provided on the first surface 112. The electrical circuit 120 of the example device 100 includes at least one electronic component 130. The example device 100 further includes at least one dummy electronic component 150 mounted on the first surface 112. The dummy electronic component 150 is electrically isolated from the electrical circuit 120 and has a protrusion 152 from the planar circuit board 110 that is greater than protrusion of each of the at least one electronic component 130 of the electrical circuit 120.

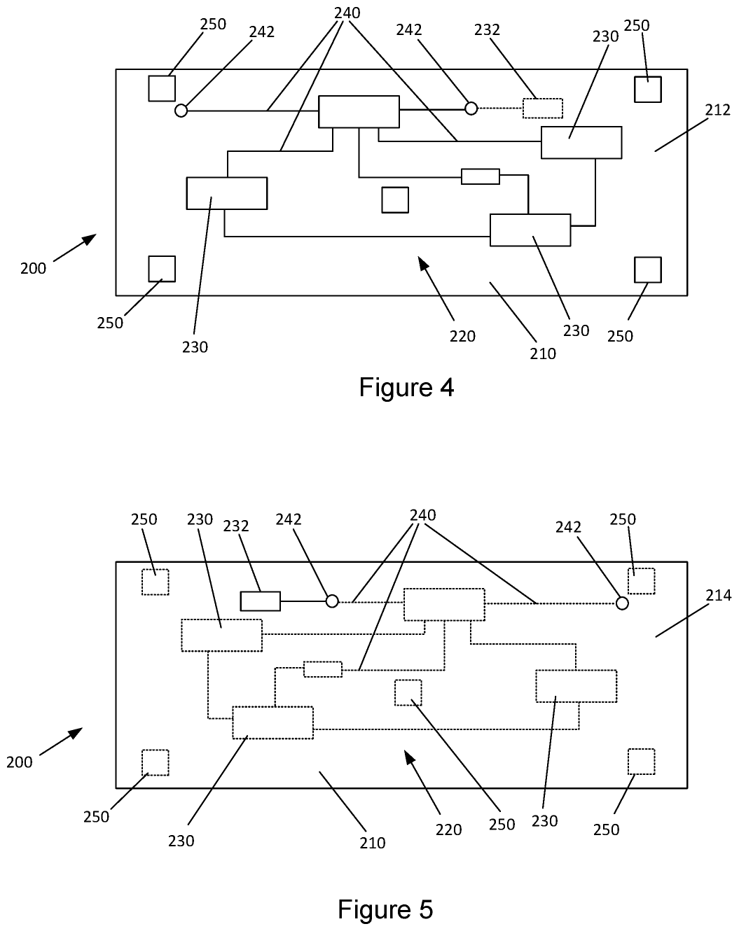

FIG. 2 illustrates an example device with an electrical circuit on a circuit board. FIGS. 3-5 illustrate various views of the example device 200 of FIG. 2. In particular, FIG. 3 illustrates a side view of the example device 200, FIG. 4 illustrates a top view of the example device of the example device 200, and FIG. 5 illustrates a bottom view of the example device 200.

The example device 200 of FIGS. 2-5 includes a substrate which forms a planar circuit board 210. The planar circuit board 210 may be sized for a particular application and to accommodate the desired circuit or components to be mounted thereon. The planar circuit board 210 may be formed of various materials, such as non-conductive materials including fiberglass, for example. In the example of FIG. 2, the planar circuit board 210 has a first surface 212 (top side of FIG. 2) and a second surface 214 (bottom side of FIG. 2) opposite the first surface 212.

The planar circuit board 210 of the example device 200 is provided with an electrical circuit formed at least on one surface. As illustrated in FIG. 2, an electrical circuit 220 is formed on the first surface 212 and includes various electronic components 230. In various examples, the electronic components 230 may include any of a variety of components, including but not limited to resistors, capacitors, switches, etc. The electronic components 230 may further include electronic packages such as processors, memory chips or the like. The electronic components 230 may be electrically coupled to form the electrical circuit 220. In one example, as illustrated in FIGS. 2-5, the electronic components 230 are coupled via electrical traces 240 that may be printed onto the planar circuit board 220.

In some examples, as illustrated in FIGS. 4 and 5, the electrical circuit 220 may be formed on both the first surface 212 and the second surface 214 of the planar circuit board 210. For example, as illustrated in FIG. 5, an electronic component may be provided on the second surface 214 of the planar circuit board 210. In this regard, the planar circuit board 210 is provided with at least one via 242 by which components (e.g., electronic component 232) on the second surface 214 may be coupled to the electronic components 230 of the electrical circuit 220 on the first surface 212 of the planar circuit board 210.

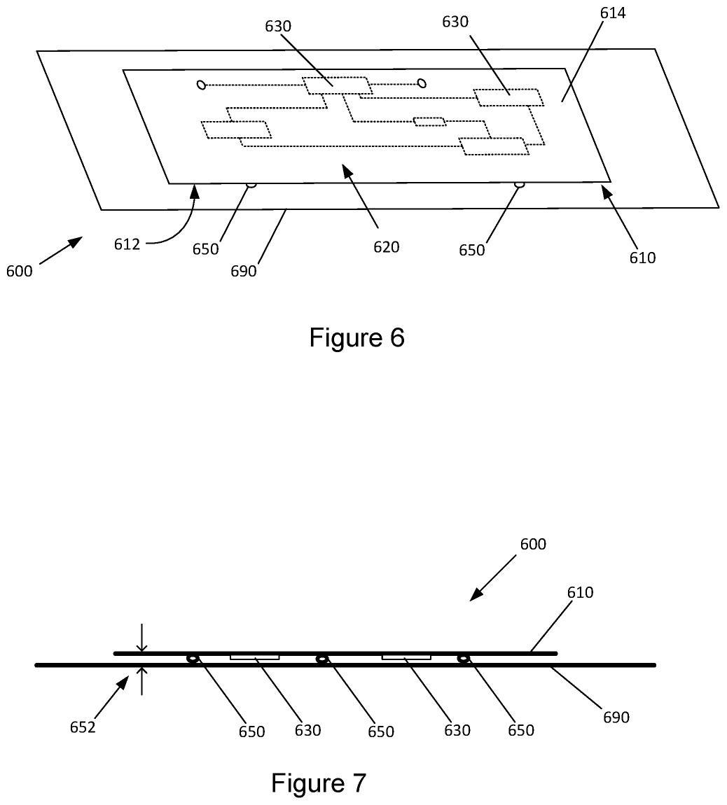

The example device 200, as illustrated in FIG. 2, further includes at least one dummy electronic component 250 mounted on the first surface 212 of the planar circuit board 210. Each of the dummy electronic components 250 is isolated from the electrical circuit 220. For example, in the example device of FIGS. 2-5, each dummy electronic component 250 is not coupled to the electrical circuit 220 via the traces 240 or otherwise. Further, as most clearly illustrated in FIG. 3, the dummy electronic components 250 have a protrusion 252 from the planar circuit board that is greater than protrusion of each of the electronic component 230 of the electrical circuit 220. Thus, when the example device 200 is mounted to a mounting surface (not shown in FIGS. 2-5), the protrusion 252 of the dummy electronic components 250 provides an air gap between the electronic components 230 of the electrical circuit 220 and the mounting surface. An example of this arrangement is described below in greater detail with reference to FIGS. 6 and 7.

The dummy electronic components 250 may be include any of a variety of electronic components. In one example, the dummy electronic components 250 are low-cost resistors. For example, resistor packages such as 0201 size resistors may be used. Such resistor packages are generally formed under tightly controlled tolerances and can, therefore, provide reliable and predictable dimensions. Further, such resistor packages are available at extremely low costs.

In various examples, assembly of the example device 200 includes positioning of the electronic components 230 onto the planar circuit board 210 to form the electrical circuit 220. In this regard, various processes may be used to mount the electronic components 230. For example, the electronic components 230 may be mounted onto the planar circuit board 210 using a pick-and-place machine or a surface-mount placement machine. In accordance with various examples, mounting of the dummy electronic components 250 may be performed using the identical process. Thus, in one example, a pick-and-place process may be used for mounting of both the electronic components 230 of the electrical circuit 220 and the dummy electronic components 240. Accordingly, no additional processing or materials, such as an adhesive, is required for positioning of the dummy electronic components 240 onto the planar circuit board 210.

Referring now to FIGS. 6 and 7, an example system is illustrated with an example device mounted on a mounting surface. In this regard, FIG. 6 illustrates a perspective view of the example system 600, and FIG. 7 provides a side view of the example system 600. The example system 600 of FIGS. 6 and 7 includes an example device 610 that is similar to the example device 200 described above with reference to FIGS. 2-5. The example device 600 of FIGS. 6 and 7 includes a first surface 612 and a second surface 614. An electrical circuit 620 is provided at least on the first surface 612 of the example device 600, the electrical circuit 620 including at least one electronic component 630. As described with reference to the example device 200 of FIGS. 2-5, the example device 610 of FIGS. 6 and 7 is provided with dummy electronic components 650 mounted on the first surface 612.

In the example system 600 of FIGS. 6 and 7, the example device 610 is mounted to a mounting surface 690. As described above, the mounting surface 690 may be any of a variety of surfaces, such as the internal frame or structure of a larger system, such as a printer or other imaging system. In some cases, the mounting surface may be formed of an electrically conductive material which may cause interference or electrical shorting of the electronic components 630 or the electrical circuit 620 of the example device 610.

In the example system 600 of FIGS. 6 and 7, the dummy electronic components 650 are provided to allow mounting of the example device 610 to the mounting surface 690 while preventing the interference or shorting of the electronic components 630 or the electrical circuit 620. In this regard, as described above with reference to FIGS. 2-5, the dummy electronic components 650 are electrically isolated from the electrical circuit 620 and have a protrusion 652 from the first surface 612 of the example device 610 that is greater than the protrusion of the electronic components 630 of the electrical circuit 620.

As most clearly illustrated in FIG. 7, the protrusion 652 of the dummy electronic components 650 provides an air gap between the electronic components 630 of the electrical circuit 620 and the mounting surface 690. In various examples, the dummy electronic components 650 may be selected to provide the desired air gap. In one example, the dummy electronic components 650 may be resistors of 0201 size and may provide an air gap of between about 200 microns. Of course, any of a variety of other dummy electronic components may be selected to provide any desired air gap.

Thus, the use of dummy electronic components 650 provides a low-cost and efficient mechanism for providing isolation of the electrical circuit 620. As noted above, any of a variety of low-cost components, such as resistor packages, may be used as the dummy electronic components. Further, assembly of the dummy electronic components 650 may be performed within the same process as the assembly of the electronic components 630 of the electrical circuit 620. For example, the dummy electronic components 650 may be mounted during the pick-and-place process used for mounting of the electronic components 630 of the electrical circuit 620. Thus, no other materials, such as an adhesive, is used for the mounting of the dummy electronic components 650.

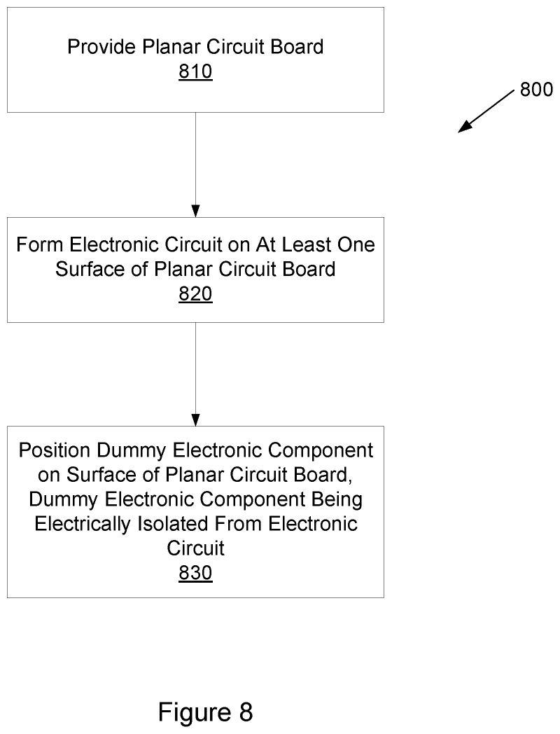

Referring now to FIG. 8, a flow chart illustrates an example method for forming an example device. In various examples, the example method 800 may be used to form an example device similar to the example devices 100, 200 described above with reference to FIGS. 1-5 above.

In accordance with the example method 800, a planar circuit board is provided (block 810). The planar circuit board may be similar to the planar circuit board 210 of the example device 200 and includes a first surface 212 and a second surface 214. As described above, the planar circuit board may be formed of a variety of materials, such as fiberglass.

Referring again to the example method 800 of FIG. 8, an electrical circuit is formed on at least one of the first surface or the second surface of the planar circuit board (block 820). The forming of the electrical circuit may include positioning various electronic components on the planar circuit board. The electronic components may be coupled to the electrical circuit through traces formed on the planar circuit board, for example.

The example method 800 further includes positioning at least one dummy electronic component on the first surface. As described above, any of a variety of components may be selected to form the dummy electronic components. In various examples, the dummy electronic components are electrically isolated from the electrical circuit. In this regard, the dummy electronic components are not coupled to the electrical circuit. Further, the dummy electronic component is provided with a protrusion from the planar circuit board that is greater than protrusion of each of the electronic components of the electrical circuit on the first surface. Thus, when mounted to a mounting surface, the dummy electronic components provide an air gap between the electronic components of the electrical circuit and the mounting surface.

Thus, in accordance with various examples described herein, dummy electronic components may be used to form an air gap between electronic components on a printed circuit board and a mounting surface which may be formed of an electrically conductive material. The use of dummy components can provide a low-cost and efficient way of allowing mounting of a printed circuit board without the risk of interference or electrical shorting.

The foregoing description of various examples has been presented for purposes of illustration and description. The foregoing description is not intended to be exhaustive or limiting to the examples disclosed, and modifications and variations are possible in light of the above teachings or may be acquired from practice of various examples. The examples discussed herein were chosen and described in order to explain the principles and the nature of various examples of the present disclosure and its practical application to enable one skilled in the art to utilize the present disclosure in various examples and with various modifications as are suited to the particular use contemplated. The features of the examples described herein may be combined in all possible combinations of methods, apparatus, modules, systems, and computer program products.

It is also noted herein that while the above describes examples, these descriptions should not be viewed in a limiting sense. Rather, there are several variations and modifications which may be made without departing from the scope as defined in the appended claims.

What is claimed is:

1. A device, comprising:
a planar circuit board with a first surface and a second surface opposite the first surface;
an electrical circuit on at least one of the first surface or the second surface, the electrical circuit including at least one electronic component; and
at least one dummy electronic component mounted on the first surface, the dummy electronic component being electrically isolated from the electrical circuit, the dummy electronic component having a protrusion from the planar circuit board that is greater than protrusion of each of the at least one electronic component of the electrical circuit.

2. The device of claim 1, wherein the at least one dummy electronic component includes a resistor.

3. The device of claim 1, wherein the at least one dummy electronic component is mounted to the first surface of the planar circuit board in the same manner as the at least one electronic component of the electrical circuit.

4. The device of claim 1, wherein the at least one dummy electronic component is mounted to the first surface of the planer circuit board without any adhesive.

5. The device of claim 1, wherein the electrical circuit is formed on the first surface and the second surface and includes at least one via formed in the planar circuit board.

6. A system, comprising:
a mounting surface;
a planar circuit board with a first surface and a second surface opposite the first surface, the planar circuit board being mounted onto the mounting surface with the first surface facing the mounting surface;
an electrical circuit on at least one of the first surface or the second surface, the electrical circuit including at least one electronic component; and
at least one dummy electronic component mounted on the first surface, the dummy electronic component being electrically isolated from the electrical circuit, the dummy electronic component having a protrusion from the planar circuit board to form an air gap between the mounting surface and each of the at least one electronic component of the electrical circuit.

7. The system of claim 6, wherein the protrusion of the dummy electronic component from the planar circuit board is greater than protrusion of each of the at least one electronic component of the electrical circuit.

8. The system of claim 6, wherein the mounting surface is formed of an electrically conductive material.

9. The system of claim 6, wherein the at least one dummy electronic component includes a resistor.

10. The system of claim 6, wherein the at least one dummy electronic component is mounted to the first surface of the planar circuit board in the same manner as the at least one electronic component of the electrical circuit.

11. The system of claim 6, wherein the at least one dummy electronic component is mounted to the first surface of the planer circuit board without any adhesive.

12. The system of claim 6, wherein the electrical circuit is formed on the first surface and the second surface and includes at least one via formed in the planar circuit board.

13. A method, comprising:
providing a planar circuit board having a first surface and a second surface;
forming an electrical circuit on at least one of the first surface or the second surface, wherein forming the electrical circuit includes positioning at least one electronic component on the planar circuit board and electrically coupled to the electrical circuit; and
positioning at least one dummy electronic component on the first surface, the dummy component being electrically isolated from the electrical circuit, the dummy electronic component having a protrusion from the planar circuit board that is greater than protrusion of each of the at least one electronic component of the electrical circuit on the first surface.

14. The method of claim 13, wherein the positioning of the at least one dummy electronic component and the positioning of the at least one electronic component of the electrical circuit are performed with an identical mounting process.

15. The method of claim 13, wherein the at least one dummy electronic component includes a resistor.
